(19) United States
(12) Patent Application Publication
(10) Pub. No.: US 2001/0021258 A1
(43) Pub. Date: Sep. 13, 2001

(54) Device and method for the reduction of sound emissions in and diagnosis of internal combustion engines

(76) Inventor: Friedmund Nagel, Zell (DE)

Correspondence Address: Jeffrey C. Hood, Conley, Rose, & Tayon, P.C., PO Box 398, Austin, TX, 78767-1246, US

(21) Appl. No.: 09/765,775

(22) Filed: Jan. 19, 2001

(30) Foreign Application Priority Data
Jul. 22, 1998 (DE) 198 32 979.2

(51) Int. Cl. H03B 29/00

(52) U.S. Cl. 381/71.4

(57) ABSTRACT

A device and a method for the reduction of sound emissions from an internal combustion engine in an exhaust line carrying an exhaust gas flow. The device has a first sound transducer for converting sound waves into first signals, that are a measure of the frequency, amplitude and phase of the sound waves, an electronic control unit for converting the first signals into second signals, and a second sound transducer, that is centrally arranged in the exhaust gas flow for converting the second signals into compensating sound waves, that have a frequency, amplitude, and phase such that the sound waves and the compensating sound waves at least partially cancel one another out. The device may also be used for diagnosis of the condition and running of the internal combustion engine. If so, the device may include a comparator unit, in which the first signals are compared with reference signals.

### FIELD OF THE INVENTION

The present invention relates to a device and a method for the reduction of sound emissions from internal combustion engines and for the diagnosis thereof.

### DESCRIPTION OF THE RELATED ART

Internal combustion engines such as those used in automobiles, motor cycles, and small-power motor appliances such as lawnmowers and power saws continuously emit exhaust gases from the combustion chamber into the surroundings. These exhaust gases are set in oscillation by the combustion process and, as a result, constitute a sound source of considerable intensity.

Silencers are conventionally arranged in the exhaust flow of internal combustion engines in order to damp the oscillations and hence reduce the sound emissions of the exhaust gases. In motor cars, two silencers, a front silencer and a rear silencer, are often used. The function of the front silencer is nowadays often assumed by a catalytic converter used for exhaust emission control. Damping of the exhaust emissions in silencers leads to increased exhaust gas back pressure and hence to engine power loss and/or increased consumption. In addition the silencers take up considerable overall space in the engine area or on the vehicle floor and constitute a significant weight addition to the vehicle.

In order to avoid these disadvantages, the prior art proposes the following methods and devices for reducing the sound emissions from internal combustion engines:

In order to reduce the sound emissions from internal combustion engines, a silencing device is proposed in U.S. Pat. No. 5,457,749. This silencing device is intended to at least partially cancel out exhaust noises by using loudspeakers arranged at the side of the exhaust gas flow to produce a cancelling noise. The loudspeakers emit sound into a secondary volume connected to the exhaust gas flow.

U.S. Pat. No. 5,222,148 relates to a method for the active damping of engine noises in the intake or exhaust area. The position of the throttle valve or the engine speed is detected by sensors and relayed to an electronic control unit. The latter activates loudspeakers arranged to the side of the gas flow in the intake or exhaust area. When activated, the loudspeakers generate a cancelling noise. Microphones fitted in the intake or exhaust area pick up the residual sound and relay a fault signal to the electronic control unit.

U.S. Pat. No. 4,665,549 relates to a device for reducing noises in a line. In this line there is a silencer with one segment directed forwards and one segment directed rearwards. In this, the loudspeaker for reducing the noises is arranged in the segment directed rearward, so that it emits sound into the narrow gap between the two segments and subsequently into the area around the silencer.

In Japanese patent application 8-137478, a device is proposed for the active reduction of noise in the exhaust lines from engines. This device has opposing pipes branching off at a 90° angle from the main exhaust line, and at the ends of the pipes, loudspeakers are arranged. Sensor and fault microphones, which, like the loudspeakers are connected to a control unit, are arranged on the exhaust line itself.

Japanese patent application 9-44167 relates to a device for the reduction of exhaust noises from engines. Like the device in JP 8-137478, this device comprises a pipe that branches off laterally from the exhaust line. At the end of the pipe is a loudspeaker that emits a cancelling noise.

Japanese patent application JP 8-123435 relates to a device for the reduction of engine intake noises. The device includes a loudspeaker arranged laterally in the intake area to emit a cancelling noise in order to compensate for intake noises.

In the Japanese patent application JP 7-98591 an arrangement for reducing noises in a line is described in general terms, the loudspeaker being arranged centrally inside the line.

Finally, a sound-emitting device is described in Japanese patent application JP 7-64568. This device can be used for the active noise control of internal combustion engines. The device has an exhaust pipe, loudspeakers arranged to the side of the exhaust pipe, and a coolant to cool the rear sides of the exhaust pipe.

### SUMMARY OF THE INVENTION

Various embodiments of a device configured to reduce the sound emissions of internal combustion engines by generating a compensating sound are disclosed. In some embodiments, this device reduces sound emissions without using a silencer or using only small silencers.

This device may, in some embodiments, be configured to reduce sound emissions from an internal combustion engine in an exhaust line carrying an exhaust gas flow. For this purpose, the device may include a first sound transducer configured to convert sound waves into first signals that are a measure of the frequency, amplitude and phase of the sound waves. The device may also include an electronic control unit configured to convert the first signals into second signals and a second sound transducer, arranged centrally in the exhaust gas flow, configured to convert the signals into compensating sound waves that have a frequency, amplitude and phase such that the sound waves and the compensating sound waves at least partially cancel one another out.

As used herein, the term exhaust line includes the entire exhaust routing from the internal combustion engine to the tail pipe outlet, including the exhaust manifold, catalytic converter and any silencers.

The first sound transducer may include a microphone configured to pick up the sound waves emitted by the exhaust gas flow and to convert them into a first signal. The first signal may be an electrical or optical signal and is a measure of the frequency, amplitude and phase of the sound waves at the sound transducer location. The electronic control unit is configured to convert the first signal into a second signal. The second sound transducer may include a loudspeaker. Based on the second signal, the second transducer is configured to emit compensating sound waves that have a frequency, amplitude and phase such that the sound waves and the compensating sound waves at least partially cancel one another out. The sound waves and the compensating sound waves may have the same frequency and amplitude and opposite phase. The amplitude of the sound waves is preferably greater than the amplitude of the compensating sound waves, however, so that any residual sound of the internal combustion remains audible.

This way, the residual sound may warn others of approaching vehicles or may give the vehicle a desired “sound.” It may also be desirable to retain an engine residual sound because if there is virtually complete compensation of the exhaust sound, other noises may acoustically come to the fore, and this effect may be undesirable.

The second sound transducer is arranged centrally in the exhaust gas flow from the internal combustion engine. The arrangement of the second sound transducer directly in the exhaust pipe allows its effect to be exerted directly on the sound waves emitted by the exhaust gases. The central arrangement in the exhaust gas flow is chosen because the laterally limited, symmetrical acoustic conditions thereby achieved significantly improve the efficiency of the sound compensation and simplify the sound compensation device as a whole. In particular, this arrangement avoids sound compensation inaccuracies due to differences in the travel time of the sound waves from several decentralized loudspeakers and unwanted interference that might occur in a decentralized and, in particular, an opposing arrangement of a plurality of loudspeakers. Above all, a symmetrical construction also creates controlled acoustic conditions.

A preferred embodiment of the present invention also provides for a central arrangement of the first sound transducer in the exhaust gas flow, since in this way the first sound transducer detects the frequency, amplitude and phase of the sound directly at the point where the second sound transducer is configured to compensate for this sound. Furthermore, in this case the first sound transducer can be combined with the second sound transducer to form a more compact unit that interferes less with the exhaust gas flow in the exhaust pipe and thereby improves the efficiency of the sound compensation. This unit can be made particularly compact if the first sound transducer is arranged within the second sound transducer. In this case, the first sound transducer may simply be arranged in a cut-out in the second transducer that is spatially surrounded but still separate from the latter. The two sound transducers may, however, also be fully integrated with one another to form a single, integral component.

In the context of the present disclosure, the term “central” may also include an essentially central, or concentric, arrangement of the sound transducers. According to some embodiments, the device may also include multiple first and second sound transducers. In such embodiments, the first and second sound transducers are then arranged essentially centrally and in such a way that they ensure symmetrical acoustic conditions.

A slight deviation from the geometrically central arrangement may be indicated by a sound field analysis at the point of mounting of the first or second sound transducer. For example, a slight deviation may occur when the main direction of propagation of the sound does not run axially parallel to the longitudinal axis of the exhaust line or to the direction of propagation of the exhaust gas flow.

The sound registered may be subjected to one or more processing stages in an electronic control unit in order to select the compensating sound as accurately as possible.

For example, a microprocessor may perform a Fourier analysis. The use of a microprocessor may also allow the compensating sound emission to be controlled according to a characteristics map. For example, a characteristics map may allow the sound emission to be controlled as a function of parameters that describe the condition of the exhaust gas sound waves or as a function of vehicle or engine parameters such as speed, engine speed or accelerator position. For example, as the speed or engine speed increases, the external sound level of the vehicle may be kept constant by increasing the percentage compensation of the exhaust sound. This may be achieved by adjusting the amplitude of the compensating sound waves more and more relative to the amplitude of the sound waves. A microprocessor may also facilitate adaptation of the sound wave compensation, such as from greater to lesser compensation, for instance.

The second sound transducer may preferably be arranged in the exhaust line in the direction of the exhaust gas flow so that the compensating sound waves are emitted in the direction of flow of the exhaust gas flow. The second sound transducer is thereby protected against direct exposure to the exhaust gases and hence also against wear and contamination. At the same time, the second sound transducer may be advantageously shielded from the exhaust gas flow by a streamlined cover. This may reduce interference in the exhaust gas flow, such as the formation of turbulence in the exhaust gas flow as a result of mounting the second sound transducer in the exhaust gas flow. It may be particularly advantageous if the first sound transducer is also arranged in the direction of the exhaust gas flow. The first sound transducer is thereby also protected against direct exposure to the exhaust gases and hence also against wear and contamination. This furthermore avoids any impairment of the sound measurement due to the flow passing over.

Further advantages of the device according to the invention may accrue if the exhaust line, that is to say the device for collecting and diverting the exhaust gases, which preferably contains both sound transducers, also has a catalytic converter as is routinely necessary for exhaust emission treatment on internal combustion engines. It is particularly advantageous if the catalytic converter is designed and arranged in the device in such a way that a largely homogeneous sound field is produced in the space downstream of the catalytic converter. In such a sound field, the sound waves are propagated essentially in the direction of the longitudinal axis of the exhaust line. This is caused by the greater attenuation of the sound components that are propagated perpendicularly to the longitudinal axis. The attenuation is due to reflection on the walls of the catalytic converter ducts. The sound components propagated in the direction of the longitudinal axis reach the catalytic converter largely unimpeded. The second sound transducer may then be arranged and oriented in such a way that the compensating sound field likewise has compensating sound waves that are mainly propagated in the direction of the longitudinal axis of the exhaust line. This makes the sound compensation very efficient, since the compensating sound front and the sound front lie essentially parallel to one another.

A preferred embodiment of the device may also include a pipe silencer that encloses at least the space in which the second sound transducer is arranged. It may be particularly preferable if the first sound transducer is also arranged in that space. The pipe silencer may permit a further reduction of the sound emissions from the internal combustion engine. In particular, the pipe silencer may additionally absorb those sound waves that are propagated perpendicularly to the longitudinal axis of the exhaust line and cannot be directly detected and cancelled out by the compensating sound emitted from the second sound transducer.

The device according to the invention may be furthermore designed in such a way that it can easily be inserted into and removed from the exhaust line or the exhaust pipe and replaced as an integral module. This module preferably comprises the second sound transducer, more preferably also the first sound transducer and more preferably still also the electronic control unit. In practice, such a module permits ease of handling in the same way as a lambda probe. It may nevertheless be desirable to ensure that the module is fitted in the exhaust line or the exhaust pipe with the requisite accuracy in order to obtain effective sound compensation in some embodiments. This can be done, for example, by means of a precisely operated installation fixture such as one having a thread with position check.

An especially preferred embodiment of the device may also include a cooling facility for cooling the first sound transducer and/or the second sound transducer. For this purpose, the sound transducers are preferably shielded from direct exposure to the exhaust gas flow by means of a casing. For cooling, external air can be introduced into the interior of the casing through corresponding openings in the device. The cooling air may then flow past the sound transducer or sound transducers and out into the exhaust line in the direction of the exhaust gas flow. At the same time, the cooling air may prevent the occurrence of exhaust gas backflow turbulence that may impinge upon the sound transducers. The cooling air may flow automatically due to the dynamic pressure generated by the exhaust gas flow in the plane of the sound transducers. Alternately, it can be delivered into the casing under corresponding pressure such as, for example, that created by a fan. In this way the temperature of the sound transducers can be properly controlled.

The device may also be used for diagnosing the condition and operation of the internal combustion engine. For this purpose, the device may include a comparator unit for comparing the first signals from the first sound transducer to reference signals. To do this, the frequency of the sound waves in question need not be precisely determined. In the event of a very narrow sound frequency spectrum, a frequency analysis can sometimes also be dispensed with and all frequencies occurring within a range can be considered as a representative frequency. It is sufficient merely to be able to differentiate meaningfully between sound waves with different frequency in order to break the sound pattern down to the necessary degree. This degree may vary according to the application and the accuracy requirements for the sound analysis.

The first signals are compared with reference signals in the comparator unit so that any deviations can be identified. An actual sound pattern is therefore compared with a reference sound pattern. This comparison permits diagnosis of the internal combustion engine, since internal combustion engines have a characteristic sound pattern for different operating conditions. Faults due to engine damage, for example, cause interference in this sound pattern. In many cases the nature of the fault can be inferred from the nature of the interference in the sound pattern. For example, the sound pattern imprinted on the exhaust gases from an internal combustion engine allows conclusions to be drawn as to the condition of the internal combustion engine. For example, conclusions may be drawn as to whether exhaust valves are not closing precisely, whether cylinders are operating despite the activation of a cylinder cut-off, or whether there is deficient compression in a cylinder. Conclusions may also be drawn that poor fuel quality is leading to engine knocking or pinking. In such an embodiment, a conventional knock sensor mounted on the cylinder block could consequently be dispensed with. At the same time, the device may afford the advantage of more precise and earlier analysis of the engine condition and the combustion sequence than can be achieved by a knock sensor registering the structure-borne noise of a component. This inference as to the condition (the permanent state of the internal combustion engine) or its operation or operating condition (the transient state of the engine), may require additional processing stages, especially additional comparative stages. Even without such additional signal processing, however, the device may still be able to routinely detect the presence of a fault.

The first signals obtained in the first sound transducer may be used in the diagnosis of an internal combustion engine. In other embodiments, parts of these first signals or secondary signals derived from these first signals may instead be used in the engine diagnosis. The first signals regularly contain information on the frequency, amplitude and phase of a plurality of sound waves. Diagnosis of the internal combustion engine may in some cases be performed simply on the basis of the frequency spectrum without reference to the amplitude and phase. In these cases, the amplitude may only need to exceed a certain limit for the first sound transducer to assign a sequence to the frequency occurring. This limit may simply be determined by the threshold sensitivity of the first sound transducer. If deviations between the actual spectrum and the reference spectrum exceeding a predetermined magnitude or significance then occur, the aforementioned conclusions can be drawn as to the condition or operation of the internal combustion engine. The reference values are predetermined for various typical operation conditions such as different engine speeds, different load ranges, and different operating parameters and may be stored in the comparator unit so that, during routine operation, a comparison of the reference values with the actual values can be made for several operating conditions. To do this, it may not be necessary to utilize all of the information from the sound compensation unit. For example, it may not be necessary to compare a full frequency spectrum of actual values with the corresponding reference values. Instead a selective comparison may be sufficient. The comparison itself may be made in a microchip or microcomputer that forms part of the comparator unit.

In some embodiments, the device may also include an output unit for emitting a warning signal in the event of at least one predetermined deviation of the first signals from the reference signals. Such a warning signal may include of a simple warning such as a warning light or a request to cease operation immediately. A warning signal as disclosed here, however, may also include a signal that automatically initiates a certain sequence such as a load adjustment, an adjustment of the ignition timing, an emergency cut-off, or a display of information indicating the existence of a certain malfunction.

The device may also comprise a selector unit for the selection of first signals corresponding to one or more specific frequency ranges for carrying out the signal comparison. This may facilitate a selective comparison of frequencies that requires less computer capacity and can therefore be performed more rapidly.

Another advantageous embodiment of the device may include a service monitoring unit for calculating and displaying when the internal combustion engine is next due for servicing on the basis of the time response of first signals compared to the reference signals for the respective operating condition. The service monitoring unit observes the time response of the actual values of first signals or parts thereof such as the frequency and draws conclusions from the time response as to when inspection of the engine will be necessary. This is possible because certain frequencies in the sound spectrum of the exhaust gases from an engine occur more frequently when the engine is ready for an inspection or overhaul. With the aid of the present embodiment, individual inspection intervals can be determined.

A method for reducing the sound emissions from internal combustion engines in an exhaust line carrying an exhaust gas flow is also disclosed. The method includes the following stages: conversion of sound waves into first signals by a first sound transducer, where the signals are a measure of the frequency, amplitude and phase of the sound waves, conversion of the first signals into second signals by an electronic control unit, and conversion of the second signals into compensating sound waves by a second sound transducer. The compensating sound waves have a frequency, amplitude and phase such that the sound waves and the compensating sound waves at least partially cancel one another out. The second sound transducer that emits the compensating sound waves is arranged centrally in the exhaust gas flow.

The method has preferred embodiments corresponding to those of the aforementioned preferred embodiments of the device. Thus, the method may accordingly encompass the diagnosis of the combustion engine.

Therefore, a device and a method for reducing the sound emissions from internal combustion engines in an exhaust line are provided. Compensating for the noise at the noise source benefits the environment and the vehicle occupants alike. By arranging the second sound transducer centrally in the exhaust gas flow, optimum symmetrical, laterally limited acoustic conditions are created. The emission of compensating sound waves can be undertaken essentially parallel to the main sound oscillation plane, thereby achieving increased sound compensation efficiency. In contrast to the prior art, in which lateral sound compensation concepts are regularly developed, the present invention is based on a central sound compensation concept. The device can easily be fitted in the exhaust line without the need to undertake major design modifications. With the addition of a comparator unit, the device may also be used for the diagnosis of internal combustion engines. The condition of an internal combustion engine can thereby be determined at any time.

### BRIEF DESCRIPTION OF THE DRAWINGS

Examples of the invention are described below with reference to the figures, in which:

FIG. 1 shows an embodiment of a device for reducing the sound emissions from internal combustion engines and having a diagnostic function; and

FIG. 2 shows a schematic diagram of the function of the device.

### List of reference numbers

1 Internal combustion engine (not shown)

2 Exhaust line

3 Exhaust gas flow

4 Widening in the exhaust line 2

5 Catalytic converter

6 Inlet of catalytic converter 5

7 Outlet of catalytic converter 5

8 Air gap insulation

9 Installation space for sound compensation unit 12

10 Perforated plate

11 Sound absorption inlay (mineral wool)

12 Sound compensation unit

13 First sound transducer (e.g. microphone)

14 Electronic control unit (microprocessor)

15 Second sound transducer (e.g. loudspeaker)

16 Cover for the sound compensation unit 12

17 Unit base

18 Openings in the unit base 17

19 Assembly opening in the exhaust line 2

20 Sound compensator for acoustic flanking path

21 Electrical lead

22 Connecting line to comparator unit 23

23 Comparator unit (not shown)

24 Lambda probe

25 Tailpipe cross-section

### DETAILED DESCRIPTION OF EMBODIMENTS

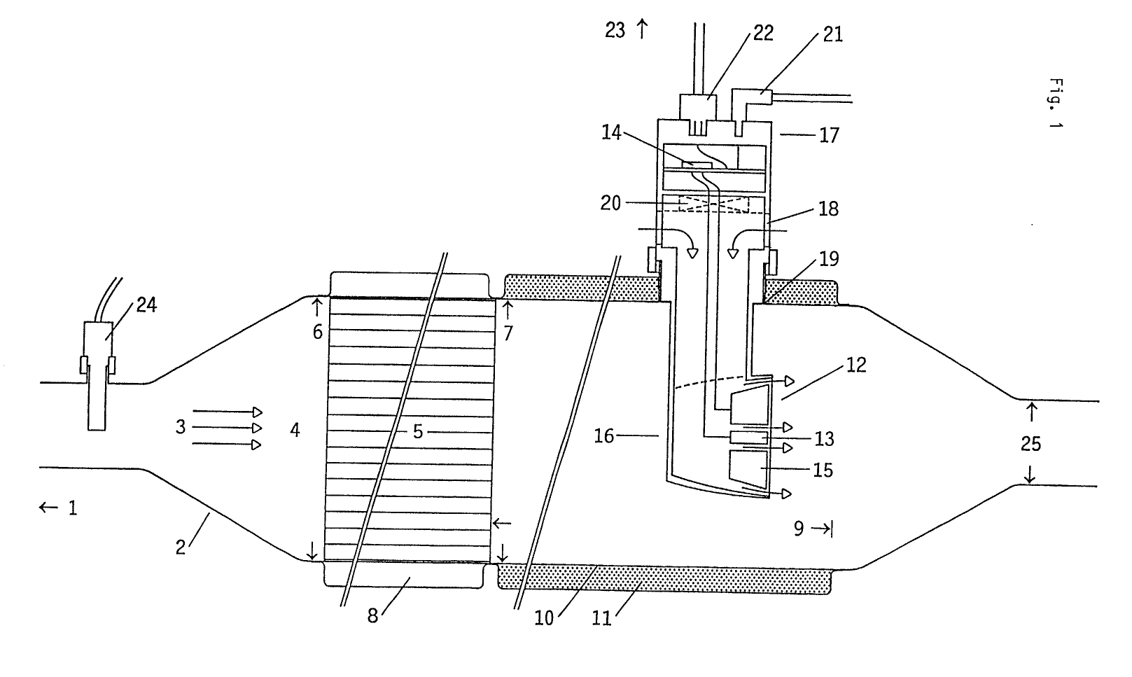

FIG. 1 shows an exhaust line 2 for the collection and removal of an exhaust gas flow 3, symbolized by multiple arrows, from an internal combustion engine 1 (not shown) which is arranged in the direction of the arrow 1. A widening 4 in the exhaust line 2 contains a catalytic converter 5 with air gap thermal insulation 8. The catalytic converter 5 may, for example, be a metal catalytic converter suitable for motor vehicles. An inlet 6 and an outlet 7 are provided for the exhaust gas flow 3. The catalytic converter's internal structure is selected in such a way that the exhaust gas flow 3 leaves the catalytic converter 5 at its outlet 7 in a largely parallel, irrotational gas flow.

The catalytic converter 5 shown here produces a rectification of the sound field of the exhaust gas flow 3. The sound field is largely non-directional upstream of the catalytic converter 5. The components of the sound waves that are perpendicular to the longitudinal axis of the catalytic converter 5, and hence also to the longitudinal axis of the exhaust line 2, are strongly damped in the catalytic converter 5. The longitudinally directed components of the sound waves are preferably allowed to pass so that a relatively well rectified, i.e. homogeneous, sound field is obtained in the space 9 downstream of the catalytic converter 5. The sound waves in the space 9 are oriented essentially in the direction of the longitudinal axis of the exhaust line 2. The sound field in the space 9 is largely parallel to the emission plane of the second sound transducer 15 and thus is largely parallel to the compensating sound plane.

On leaving the catalytic converter 5, the exhaust gas flow 3 encounters the sound compensation unit 12, which comprises a loudspeaker 15 and a microphone 13 arranged in the middle thereof. The microphone 13 is arranged in the loudspeaker 15 in order to save space and to register the sound at approximately the point where the compensating sound waves are emitted. Both the microphone 13 and the loudspeaker 15 are arranged in the direction of the exhaust gas flow 3 in order to generally avoid their being exposed to the exhaust gases. This protects them from being contaminated by the exhaust gas flow 3 and damaged by fine particles detached from the catalytic converter. It also reduces the flow resistance of the sound compensation unit 12.

FIG. 1 also shows a lambda probe 24 and its lead. The probe is mounted in the exhaust line 2 in a similar way to the sound compensating unit 12.

The device illustrated in FIG. 1 also has a pipe silencer that is arranged along one section and around the circumference of the exhaust line 2. The section that the pipe silencer is arranged on extends from the outlet 7 of the catalytic converter 5 to the end of the widening 4 downstream of the sound compensation unit 12.

In the space 9 of the exhaust line 2 in which the sound compensation unit 12 is arranged, the pipe silencer has a sound absorption inlay 11. The sound absorption inlay may, for example, be mineral wool. The sound absorption inlay 11 fills the space between the wall of the exhaust line 2 and the outer wall of the pipe silencer. The wall of the exhaust line 2 is made of a perforated plate 10 in this section. The pipe silencer primarily absorbs those sound waves that are propagated perpendicularly to the longitudinal axis of the exhaust line. The sound compensation unit 12, by contrast, primarily reduces the components of the exhaust gas sound field that are propagated in the direction of the longitudinal axis of the exhaust line 2. The sound compensation unit 12 is arranged centrally in the exhaust line 2 so that symmetrical and thus fully calculable acoustic conditions are obtained. It is arranged in the widening 4 where the requisite installation cross-section for the sound compensation unit 12 is already available without additional change to the cross-section.

The sound compensation unit 12 is shielded from the exhaust gas flow 3 coming from the catalytic converter 5 by a streamlined casing 16. This casing extends from the middle of the exhaust line 2, where the sound transducers are located, to the unit base 17 on the wall of the exhaust line 2. Openings remote from the flow are left in the casing 16 for the microphone 13 and the loudspeaker 15. The microphone 13 and the loudspeaker 15 are arranged inside the casing 16 in such a way that gaps through which cooling air can flow are left between the microphone 13 and the loudspeaker 15 and between the loudspeaker 15 and the casing 16. External air can be introduced into the casing 16 through corresponding openings 19 in the unit base 17 for cooling the sound compensation unit 12. The cooling air surrounding the sound transducers can then flow outwards into the exhaust line into the exhaust gas flow, preventing the occurrence of exhaust gas backflow turbulence, which might impinge upon the microphone 13 or the loudspeaker 15. The direction of flow of the cooling air is indicated by the arrows inside the casing 16. The cooling air may flow automatically due to the dynamic pressure generated by the exhaust gas flow 3 in the exhaust lines or it may be delivered into the casing 16 under corresponding pressure created by a fan. In this way, the temperature of the sound transducers 13, 15 can be properly controlled.

Power is supplied to the sound compensation unit 12 by way of the electrical lead 21. The module comprising sound compensation unit 12, including unit base 17, electronic control unit 14 and any sound compensator 20, is introduced into the exhaust line 2 through an assembly opening 19 and fixed therein by means of a precise screw thread or a similarly precisely functioning socket connector. The device according to the invention can thereby be easily fitted and detached, making it easy to replace in the event of damage. It may, however, be desirable if the sound compensation unit 12 is accurately fixed and adjusted so that the sound compensation always functions reliably. Additionally, it may be fitted in the exhaust line 2 so that it cannot vibrate.

A sound compensator 20, which is arranged inside the unit base 17 just above the openings 18, is provided for the acoustic flanking path that might occur through the casing 16 and the openings 18 in the unit base 17. The sound compensator 20 functions on the principle outlined above.

The illustrated device also has an electronic control unit 14. The electronic control unit may be a microprocessor. The electronic control unit 14 is connected by leads to the microphone 13 and the loudspeaker 15 of the sound compensation unit 12. The electronic control unit 14 is arranged in the unit base 17, where it is protected from excessive thermal stresses.

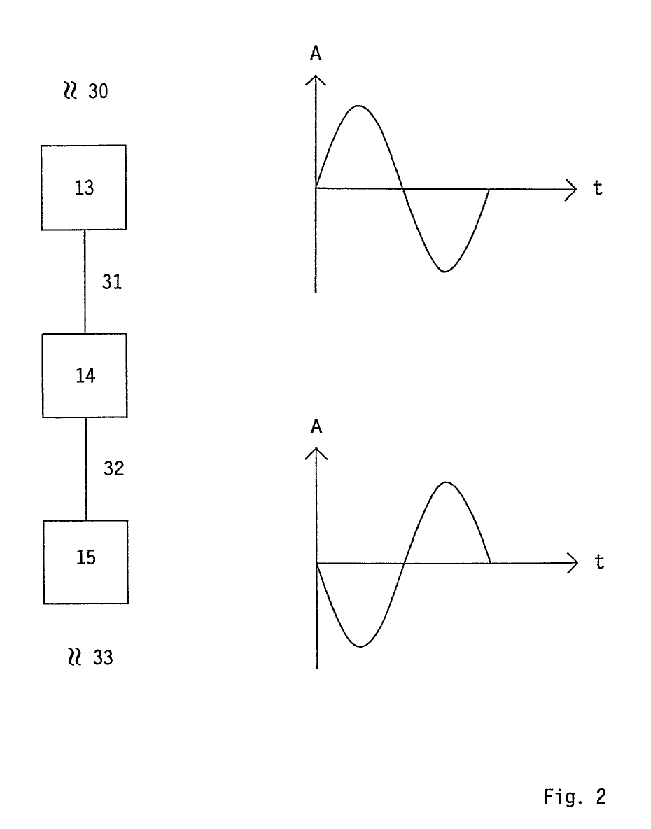

FIG. 2 shows a schematic diagram of the working principle of the embodiment illustrated in FIG. 1. The exhaust gas sound waves 30 encounter the first sound transducer 13, which may be a microphone, and are converted into first signals 31, which, for example, may be electrical signals. The first signals 31 are a measure of the frequency, amplitude and phase of the sound waves 30. In the electronic control unit 14, the first signals 31 are processed and converted into second signals 32, which have a 180° phase offset in relation to the first signals 31. At the same time, the sound waves 30 may in some embodiments also be subjected, for example, to a Fourier analysis, in order to break the complex sound pattern down into elementary sinusoidal oscillations. Such a sinusoidal oscillation is shown in FIG. 2. The second signals 32 are then delivered to the second sound transducer 15, which may be a loudspeaker. The second sound transducer then emits compensating sound waves 33 based on the second signals 32. If, for example, a Fourier analysis has been performed, one elementary compensating wave is emitted per elementary wave. Such an elementary compensating wave is represented in FIG. 2. The compensating sound waves 33 have an inverse phase, i.e., are offset by 180°, compared to the associated exhaust gas sound waves 30, the same frequency, and either the same amplitude or a reduced amplitude in order to achieve a required residual sound level.

The present embodiment of the device shown in FIG. 1 furthermore includes facilities for diagnosing the condition or operation of the internal combustion engine 1. From the first sound transducer 13 the first signals 31 representing the sound in the exhaust line 2 are fed to the electronic control unit 14 where they are processed. A comparator unit 23, which is integrated into the engine management system and is connected by way of a lead 22 to the electronic control unit and/or directly to the first sound transducer 13, either receives the requisite data for the comparison of reference and actual values described above from the electronic control unit 14, or receives the first signals directly from the first sound transducer 13.

Downstream of the sound compensation unit 12 the exhaust line 2 narrows to a smaller cross-section 25. The degree of sound compensation can here be adjusted to a desired level by varying the amplitude of the compensating sound waves 33. The desired amplitude level may be less than the amplitude of the exhaust gas sound waves in order to obtain a residual sound. The residual sound may serve a warning function and may also serve to create a specific, desired “sound.” This method of sound compensation is not only weight-saving and compact but also simple and hence economical. The present embodiment of the device also allows simple and economical diagnosis of the condition and operation of an internal combustion engine.

I claim:

1. Device for reducing the sound emission from internal combustion engines (1) in an exhaust line (2), which carries an exhaust gas flow (3), having:
(a) at least one first sound transducer (13) for converting sound waves (30) into first signals (31), which are a measure of the frequency, amplitude and phase of the sound waves (30),
(b) an electronic control unit (14) for converting the first signals (31) into second signals (32) and
(c) at least one second sound transducer (15), which is arranged centrally in the exhaust gas flow (3), for converting the second signals (32) into compensating sound waves (33), which have a frequency, amplitude and phase, such that the sound waves (30) and the compensating sound waves (33) at least partially cancel one another out.

2. Device according to claim 1, in which the second sound transducer (15) is arranged in the direction of the exhaust gas flow (3), so that the compensating sound waves (33) are emitted in the direction of flow of the exhaust gas flow (3).

3. Device according to claim 2, in which the second sound transducer (15) is shielded against the exhaust gas flow (3) by a streamlined casing (16).

4. Device according to claim 1, in which the first sound transducer (13) is arranged centrally in the exhaust gas flow (3).

5. Device according to claim 1, in which the first sound transducer (13) is arranged in the second sound transducer (15).

6. Device according to claim 1, which contains a catalytic converter (5) having an inlet (6) and an outlet (7) for the exhaust gas flow (3).

7. Device according to claim 6, in which the catalytic converter (5) is designed and arranged in such a way that a largely homogeneous sound field is produced in the space (9) downstream of the catalytic converter (5), in which field the sound waves (30) are propagated essentially in the direction of the longitudinal axis of the exhaust line (2).

8. Device according to claim 1, which furthermore has a pipe silencer, which encloses a space (9), in which at least the second sound transducer (15) is arranged.

9. Device according to claim 1, furthermore having a cooling device for cooling the first sound transducer (13) and/or the second sound transducer (15).

10. Device according to claim 1, furthermore having a comparator unit (23) for comparing the first signals (31) from the first sound transducer (13) with reference signals.

11. Device according to claim 10, furthermore having an output unit for emitting a warning signal at the occurrence of a predetermined deviation of the first signals (31) coming from the first sound transducer (13) from the reference signals.

12. Device according to claim 10, furthermore having a service monitoring unit for calculating and displaying when the internal combustion engine (1) is next due for servicing on the basis of the time response of the first signals (31) coming from the first sound transducer (13) compared to the reference signals.

13. Method for reduction of the sound emissions from internal combustion engines (1) in an exhaust line (2) carrying an exhaust gas flow (3), the method having the following stages:
(a) conversion of sound waves (30) into first signals (31) in at least one first sound transducer (13), the signals (31) being a measure of the frequency, the amplitude and the phase of the sound waves (30),
(b) conversion of the first signals (31) into second signals (32) in an electronic control unit (14), and
(c) conversion of the second signals (32) into compensating sound waves (33) in at least one second sound transducer (15), the compensating sound waves (33) having a frequency, an amplitude and phase such that the sound waves (30) and the compensating sound waves (33) at least partially cancel one another out, and the second sound transducer (15) emitting the compensating sound waves (33) centrally in the exhaust gas flow (3).

14. Method according to claim 13, having a further processing stage, in which the first signals (31) from the first sound transducer (13) are compared with reference signals in a comparator unit (23).

15. Method according to claim 13, in which a warning signal is emitted by means of an output unit at the occurrence of at least one predetermined deviation of the first signal (31) coming from the first sound transducer (13) from reference signals.

16. Method according to claim 13, in which a service monitoring unit calculates and displays the date when the internal combustion engine (1) is next due for servicing on the basis of the time response of the first signals (31) from the first sound transducer (13) compared to reference signals.

17. Device for reducing the sound emissions from internal combustion engines (1) in an exhaust line (2), which carries an exhaust gas flow (3), having:
(a) at least one first sound transducer (13) for converting sound waves (30) into first signals (31), which are a measure of the frequency, amplitude and phase of the sound waves (30),
(b) an electronic control unit (14) for converting the first signals (31) into second signals (32) and
(c) at least one second sound transducer (15), which is arranged centrally in the exhaust gas flow (3), for converting the second signals (32) into compensating sound waves (33), which have a frequency, amplitude and phase, such that the sound waves (30) and the compensating sound waves (33) at least partially cancel one another out.
(d) the second sound transducer (15) being shielded against the exhaust gas flow (3) by a streamlined cover, and
(e) being cooled by cooling air, the cooling air flowing past the sound transducer (15) out into the exhaust line (2) in the direction of the exhaust gas flow (3), thereby at the same time preventing the occurrence of exhaust gas backflow turbulence.

18. Device according to claim 17, the device containing a catalytic converter (5) having an inlet (6) and an outlet (7) for the exhaust gas flow (3), which is designed and arranged in such a way that a largely homogeneous sound field is produced in the space (9) downstream of the catalytic converter (5), in which field the sound waves (30) are propagated essentially in the direction of the longitudinal axis of the exhaust line (2).

19. Device according to claim 17, the device having a device for diagnosing the condition and the running of the internal combustion engine (1).

20. Method for reduction of the sound emissions from internal combustion engines (1) in an exhaust line (2) carrying an exhaust gas flow (3), the method having the following stages:
(a) conversion of sound waves (30) into first signals (31) in at least one first sound transducer (13), the signals (31) being a measure of the frequency, the amplitude and the phase of the sound waves (30),
(b) conversion of the first signals (31) into second signals (32) in an electronic control unit (14),
(c) conversion of the second signals (32) into compensating sound waves (33) in at least one second sound transducer (15), the compensating sound waves (33) having a frequency, an amplitude and phase such that the sound waves (30) and the compensating sound waves (33) at least partially cancel one another out, and the second sound transducer (15) emitting the compensating sound waves (33) centrally in the exhaust gas flow (3),
(d) shielding of the second sound transducer (15) against the exhaust gas flow (3) by means of a streamlined cover, and
(e) cooling of the second sound transducer (15) by means of cooling air, the cooling air flowing past the sound transducer (15) out into the exhaust line (2) in the direction of the exhaust gas flow (3)and thereby at the same time preventing the occurrence of exhaust gas backflow turbulence

21. Method according to claim 20, having a further processing stage, in which by means of a catalytic converter (5), correspondingly designed and arranged, a largely homogeneous sound field is produced in the space (9) downstream of the catalytic converter (5), in which field the sound waves (30) are propagated essentially in the direction of the longitudinal axis of the exhaust line (2).

22. Method according to claim 20, having a further processing stage, in which the condition and running of the internal combustion engine is diagnosed by means of a device.

23. A device configured to reduce sound emission from an internal combustion engine in an exhaust line which carries an exhaust gas flow, comprising:
at least one first sound transducer configured to convert sound waves into first signals, wherein the first signals are a measure of a frequency, amplitude and phase of the sound waves;
an electronic control unit configured to convert the first signals into second signals; and
at least one second sound transducer centrally arranged in the exhaust gas flow and configured to convert the second signals into compensating sound waves; wherein the sound waves and the compensating sound waves at least partially cancel one another out.

24. The device according to claim 23, wherein the at least one second sound transducer is further arranged in a direction of the exhaust gas flow so that the compensating sound waves are emitted in the direction of the exhaust gas flow.

25. The device according to claim 24, further comprising a streamlined casing configured to shield the at least one second sound transducer from the exhaust gas flow.

26. The device according to claim 23, wherein the at least one first sound transducer is centrally arranged in the exhaust gas flow.

27. The device according to claim 23, wherein the at least one first sound transducer is arranged within the at least one second sound transducer.

28. The device according to claim 23, further comprising a catalytic converter comprising an inlet and an outlet for the exhaust gas flow.

29. The device according to claim 28, wherein a largely homogeneous sound field is produced in a space downstream of the catalytic converter, wherein the sound waves are propagated essentially in a direction of a longitudinal axis of the exhaust line in the largely homogeneous sound field.

30. The device according to claim 23, further comprising a pipe silencer configured to enclose a space in which the at least one second sound transducer is arranged.

31. The device according to claim 23, further comprising a cooling device configured to cool one or more of: the at least one first sound transducer and the at least one second sound transducer.

32. The device according to claim 23, further comprising a comparator unit configured to compare the first signals from the at least one first sound transducer with reference signals.

33. The device according to claim 32, further comprising an output unit configured to emit a warning signal if a predetermined deviation of the first signals from the reference signals occurs.

34. The device according to claim 32, further comprising a service monitoring unit configured to calculate and display when the internal combustion engine is next due for servicing based on a time response of the first signals compared to the reference signals.

35. A method for reducing sound emissions from an internal combustion engine in an exhaust line carrying an exhaust gas flow, the method comprising:
converting sound waves into first signals using at least one first sound transducer, wherein the first signals are a measure of a frequency, amplitude and phase of the sound waves;
converting the first signals into second signals using an electronic control unit;
converting the second signals into compensating sound waves using at least one second sound transducer, wherein the at least one second sound transducer is centrally arranged in the exhaust gas flow; and
emitting the compensating sound waves using the at least one second sound transducer; wherein the compensating sound waves and the sound waves at least partially cancel each other out.

36. The method according to claim 35, further comprising comparing the first signals to reference signals.

37. The method according to claim 35, further comprising emitting a warning signal at an occurrence of at least one predetermined deviation of the first signal from reference signals.

38. The method according to claim 35, further comprising calculating and displaying a date when the internal combustion engine is next due for servicing based on a time response of the first signals compared to reference signals.

39. A device configured to reduce sound emissions from an internal combustion engine in an exhaust line that carries an exhaust gas flow, comprising:
at least one first sound transducer configured to convert sound waves into first signals, wherein the first signals are a measure of a frequency, amplitude and phase of the sound waves;
an electronic control unit configured to convert the first signals into second signals;
at least one second sound transducer centrally arranged in the exhaust gas flow and configured to convert the second signals into compensating sound waves wherein the sound waves and the compensating sound waves at least partially cancel one another out;
a streamlined cover configured to shield the at least one second sound transducer from the exhaust gas flow; and
openings configured to allow cooling air to flow past the at least one sound transducer and out into the exhaust line in a direction of the exhaust gas flow.

40. The device according to claim 39, further comprising a catalytic converter comprising an inlet and an outlet for the exhaust gas flow, wherein a largely homogeneous sound field is produced in a space downstream of the catalytic converter, wherein the sound waves are propagated essentially in a direction of a longitudinal axis of the exhaust line in the largely homogeneous sound field.

41. The device according to claim 39, further comprising a diagnostic device configured to diagnose a condition and an operation of the internal combustion engine.

42. A method for reducing sound emissions from an internal combustion engine in an exhaust line carrying an exhaust gas flow, the method comprising:
converting sound waves into first signals using at least one first sound transducer, wherein the signals are a measure of a frequency, amplitude and phase of the sound waves;
converting the first signals into second signals using an electronic control unit;
converting the second signals into compensating sound waves using at least one second sound transducer, wherein the at least one second transducer is centrally arranged if the exhaust gas flow, wherein the sound waves and the compensating sound waves at least partially cancel one another out;
emitting the compensating sound waves using the at least one second sound transducer;
shielding the at least one second sound transducer against the exhaust gas flow; and
cooling the at least one second sound transducer using cooling air; wherein the cooling air flows past the sound transducer and out into the exhaust line in a direction of the exhaust gas flow.

43. The method according to claim 42, further comprising producing a largely homogeneous sound field in a space downstream of a catalytic converter in which the sound waves are propagated essentially in a direction of a longitudinal axis of the exhaust line.

44. The method according to claim 42, further comprising diagnosing a condition and operation of the internal combustion engine.
